(19) United States
(12) Patent Application Publication
(10) Pub. No.: US 2006/0148173 A1
(43) Pub. Date: Jul. 6, 2006

(54) Method for manufacturing electronic memory devices integrated in a semiconductor substrate including non-volatile memory matrix and associated circuitry

(75) Inventor: Luca Pividori, Curno (BG) (IT)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics S.r.l., Agrate Brianza (MI) (IT)

(21) Appl. No.: 11/302,612

(22) Filed: Dec. 14, 2005

(30) Foreign Application Priority Data
Dec. 14, 2004 (IT) MI2004A 002372

(51) Int. Cl. H01L 21/336; H01L 21/461

(52) U.S. Cl. 438/258; 438/706

(57) ABSTRACT

The method is for manufacturing electronic memory devices on a semiconductor substrate including a non-volatile memory matrix and associated circuitry. The method includes forming a first insulation layer, a conductive layer and a second insulation layer. A resist mask is formed corresponding with the memory matrix to define a predetermined geometry in the second insulation layer. The exposed portions of the second insulation layer are isotropically etched. Also, a conformal protective layer is formed and removed via a second highly selective etching step to form portions of the conformal protective layer on side walls of the resist mask and of the insulation layer. A third isotropic etching step removes the insulation layers left exposed by the resist mask and by the portions of the protective layer. The portions of the conformal protective layer and of the resist mask are then removed.

### FIELD OF THE INVENTION

The present invention relates to semiconductor memories, and particularly to a method for manufacturing electronic memory devices integrated on a semiconductor substrate and including a non-volatile memory matrix and associated circuitry.

### BACKGROUND OF THE INVENTION

Conventional semiconductor-integrated memory electronic devices of the Flash Electrically Programmable Read Only Memory (Flash-EPROM) type include a plurality of non-volatile memory cells. Each single non-volatile memory cell comprises a MOS transistor wherein the gate electrode, placed above the channel region, is floating, i.e. it has a high impedance continuously towards all the other terminals of the same cell and the circuit wherein the cell is inserted. This floating gate is insulated from the channel region via a thin oxide layer called a tunnel oxide.

The cell also comprises a second electrode, called a control gate, which is driven through suitable control voltages. This control gate is insulated from the floating gate via a further oxide layer called an interpoly oxide. This interpoly oxide layer is, for example, made of a plurality of insulating layers referred to as ONO (Oxide Nitride Oxide). The other electrodes of the transistor are the usual drain, source and body terminals.

By applying suitable voltage values to the cell terminals, it is possible to vary the amount of the charge present in the floating gate, for example by using the known phenomena of Fowler-Nordheim Tunneling and/or Channel Hot Electrons Injection. This allows to place the transistor in two logic states: a first state with a relatively “high” threshold voltage and a second state with a “low” threshold voltage.

Since the floating gate has a high impedance towards any other terminal of the cell, the charge stored therein can stay for an undetermined time, even if the supply of the circuit wherein it is inserted is removed. The cell thus has non-volatile memory characteristics. However, for these types of devices, the capacity to retain the information over time inside the memory cells essentially depends on the quality and perfection with which some layers of material are formed which are critical during the manufacturing process of these devices.

In particular, in the electronic memory devices of the Flash EPROM type, the critical layers are represented by the tunnel oxide layer and by the interpoly oxide layer. The interpoly oxide layer can also play a further role when it is used as a dielectric layer for the formation of other devices integrated on the same conductive substrate whereon the memory cells of the Flash type are formed. This insulation layer can be, for example, used as dielectric layer to form capacitors (voltage pumps) necessary to generate the voltages internally supplied to the different circuits of the memory device.

To explain the technical problems linked to the manufacturing of these critical layers, with reference to FIGS. 1 to 6, the conventional process steps to manufacture electronic memory devices comprising a matrix of non-volatile memory cells and a associated circuitry are discussed below. In particular, on a semiconductor substrate 1 the selective formation of a first insulation layer, not shown in the figures, is carried out to define active areas for the memory matrix 2 and for the circuitry 3. In these active areas, a second insulation layer 4, called the tunnel oxide in the memory cells of the Flash type, and a first conductive layer 5, for example of polysilicon are formed, as shown in FIG. 1.

The polysilicon layer 5 is selectively removed via a conventional photolithographic process to form floating gate regions 6 of the memory matrix and it is completely removed from the circuitry 2, as shown in FIG. 2. A third insulation layer 7, called interpoly oxide, for example ONO, is then deposited on the whole semiconductor substrate 1 as shown in FIG. 3.

Through a conventional photolithographic process using a resist mask 8, generally of the DUV (Deep Ultra Violet) type, called mask MATRIX, a removal/etching step of the second insulation layer 7 of ONO follows. This etching step is generally carried out via an etching step of the dry type.

An etching step of the polysilicon layer 3 to form floating gate regions of the cells of the memory matrix 2, the etching step of the insulation layers left exposed by the mask 8 in the circuitry 3, and the etching step of the mask 8 itself then follow, as shown in FIG. 5. This last etching step of the insulation layers left exposed by the mask 8, is conventionally carried out through a wet etching step of the isotropic type.

As shown in FIG. 6, the wet etching step of the isotropic type can cause a removal of the interpoly layer 7 below the mask 8. In fact, the solution used to carry out the wet etching step of the isotropic type can penetrate below the resist layer of the DUV type the mask 8 is made of. This resist layer of the DUV type is in fact particularly sensitive, i.e. easily removable, via the solution used to carry out the wet etching step of the isotropic type. Moreover, this type of DUV resist shows a lower capacity of adhesion to the underlying layers whereon it is distributed (these latter being of nitride/oxide/poly or metal,) also because this layer is very sensitive to the presence of contaminating elements, such as amines, which are formed on the surface to be covered.

This problem is particularly evident when thicknesses of layers of 0.15 μm or lower are defined. Under these conditions in fact some steps of removal/etching of layers, such as for example the wet etchings of the oxide layers, although being part of the procedure commonly known and adopted during the steps of formation of these electronic memory devices, achieve an even greater criticality. In fact, under these conditions, the removal phenomenon of the interpoly layer is further favored by capillarity effects of the solution used to carry out the wet etching steps of the isotropic type which penetrates below the mask 8.

A known technique to make the formation of these interpoly layers less critical requires, for example, the modification of some structures of the memory device or the introduction of a further mask to the conventional process flow. Although advantageous under several aspects, these approaches have the drawback of altering the standard process flow used to form these memory cells. Other known approaches in the manufacturing processes of these devices, use ‘less critical’ resist layers such as those of the i-line type. However, these layers are not always compatible with the dimensional and alignment performances required by the recent technologies used for forming current electronic memory devices.

The technical problem underlying the present invention is that of devising a method for manufacturing non-volatile electronic memory devices without burdening the standard process flow for forming these devices and moreover not to affect other structures constituting the memory device thus overcoming the drawbacks still limiting the manufacturing methods realized according to the prior art.

### SUMMARY OF THE INVENTION

An object of the present invention is to protect the critical layers via a protective layer, for example a photoresist, resistant to particular wet etching steps.

This and other objects are achieved by providing a method for manufacturing electronic memory devices on a semiconductor substrate including a non-volatile memory matrix and associated circuitry. The method includes forming a first insulation layer, a conductive layer and a second insulation layer. A resist mask is formed corresponding with the memory matrix to define a predetermined geometry in the second insulation layer. The exposed portions of the second insulation layer are isotropically etched. Also, a conformal protective layer is formed and removed via a second highly selective etching step to form portions of the conformal protective layer on side walls of the resist mask and of the insulation layer. A third isotropic etching step removes the insulation layers left exposed by the resist mask and by the portions of the protective layer. The portions of the conformal protective layer and of the resist mask are then removed.

### BRIEF DESCRIPTION OF THE DRAWINGS

The characteristics and advantages of the method and device according to the invention will be apparent from the following description of an embodiment thereof given by way of indicative and non limiting example with reference to the annexed drawings.

FIGS. 1 to 6 are cross-sectional views of a semiconductor substrate portion during the conventional manufacturing steps of a memory device;

FIGS. 7 to 9 are cross-sectional views of a semiconductor substrate portion during some manufacturing steps of a memory device according to the present invention.

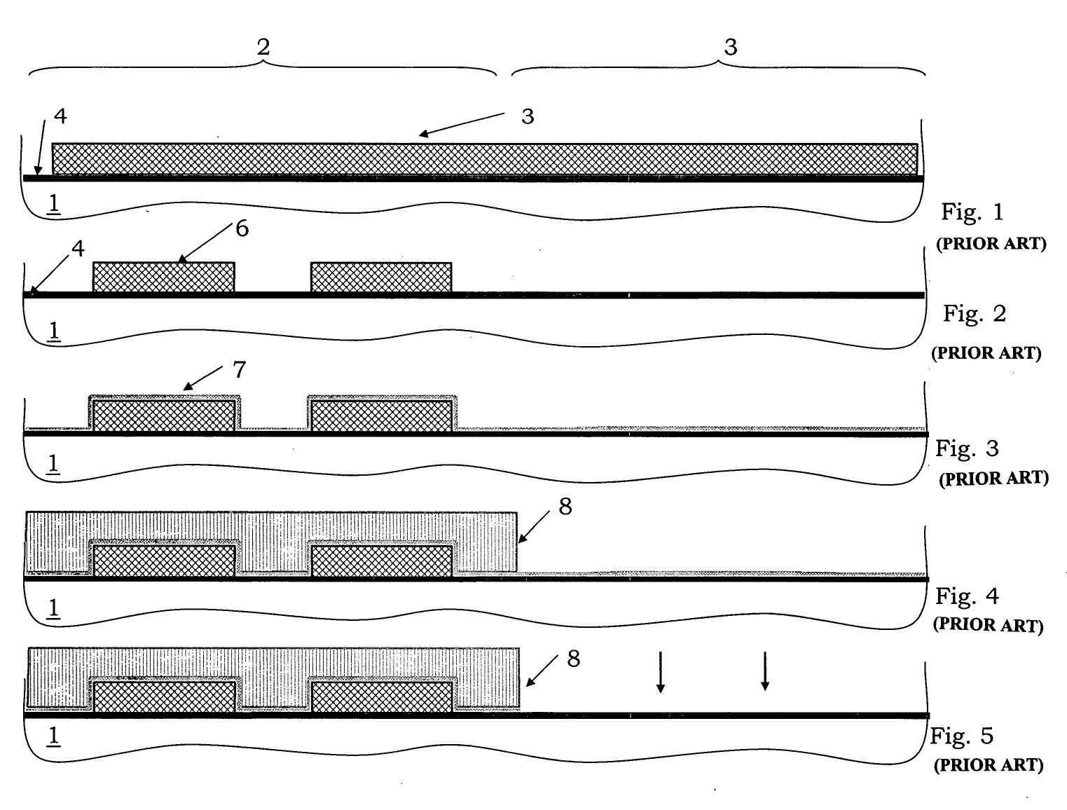

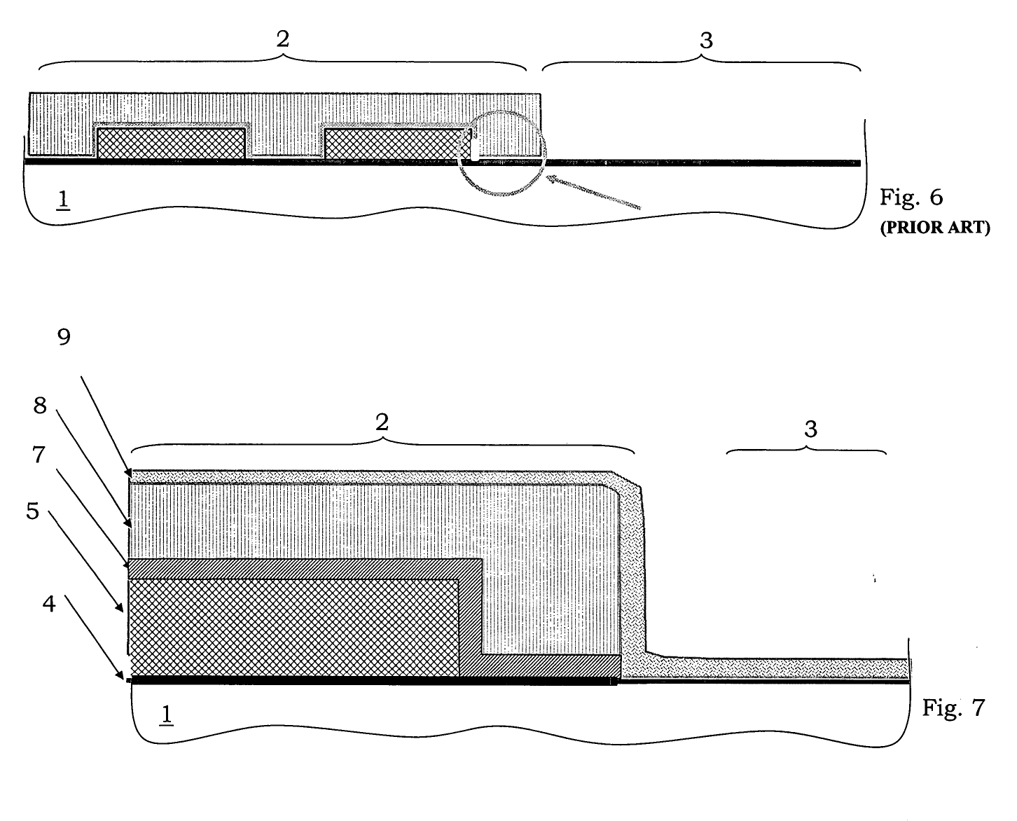

### DETAILED DESCRIPTION OF THE PREFERRED EMBODIMENTS

With reference to FIGS. 7 to 9 a method is described to manufacture electronic memory devices integrated on a semiconductor substrate 1, and comprising a non-volatile memory matrix 2 and associated circuitry. The method according to the invention is carried out with the following sequence of process steps. These steps described hereafter are not the complete process flow for the manufacturing of integrated circuits. The present invention can be put into practice together with the manufacturing techniques of the integrated circuits currently used in the field, and only those commonly used process steps being necessary for the understanding of the present invention are included.

The figures representing schematic views of portions of an integrated circuit during the manufacturing are not drawn to scale, but they are instead drawn so as to show the important characteristics of the invention. In the following description, the reference numbers used relative to the method according to the invention are the same as those used for the prior art figures with respect to the same elements.

In particular, the method according to the invention comprises the selective formation, on the surface of the semiconductor substrate 1, of a first insulation layer, not shown in the figures, to define, in the semiconductor substrate 1, active areas for the memory matrix 2 and for the associated circuitry 3. As shown in FIG. 7, in these active areas, a second insulation layer 4, called tunnel oxide for the memory cells of the Flash type, and a first conductive layer 5, for example of polysilicon, are formed.

The polysilicon layer 5 is selectively removed via a conventional photolithographic process to form floating gate regions 6 of the memory matrix and it is completely removed from the circuitry 2. A third insulation layer 7 called interpoly oxide, for example ONO, is then deposited on the whole semiconductor substrate 1. Through a conventional photolithographic process which uses a resist mask 8, generally of the DUV type, called mask MATRIX, an etching step follows, generally dry, of the second insulation layer 7 of ONO.

According to the invention, on the semiconductor substrate 1, a conformal uniform layer 9 is formed, i.e. of uniform thickness. According to the invention, this protective layer 9 is highly selective with respect to the insulation layers. Advantageously, the protective layer 9 is a layer of material sensitive to the irradiation, for example a resist layer. Advantageously, the protective layer 9 is a layer of thin material.

In the embodiment of the method according to the invention wherein the protective layer 9 is a resist layer, after having deposited the resist layer 9, without carrying out the development of this layer, a thermal treatment step is carried out to harden it. At this point of the process, on the surface of the semiconductor substrate 1, a conformal protective layer 9 is obtained, i.e. all the structures present on the semiconductor substrate 1 are coated by a resist layer 9 of uniform thickness.

In a possible embodiment, the protective layer 9 it is made of resist of the DUV type, whose thickness and dispersion parameters can be easily controlled during the conventional manufacturing processes. In a particularly advantageous embodiment, the protective layer 9 is instead a layer of BARC (Bottom Antireflective Coating). This BARC layer has the feature of being a particularly conformal layer and thus it allows to avoid possible accumulations of the protective layer 9 between the mask 8 and the semiconductor substrate 1.

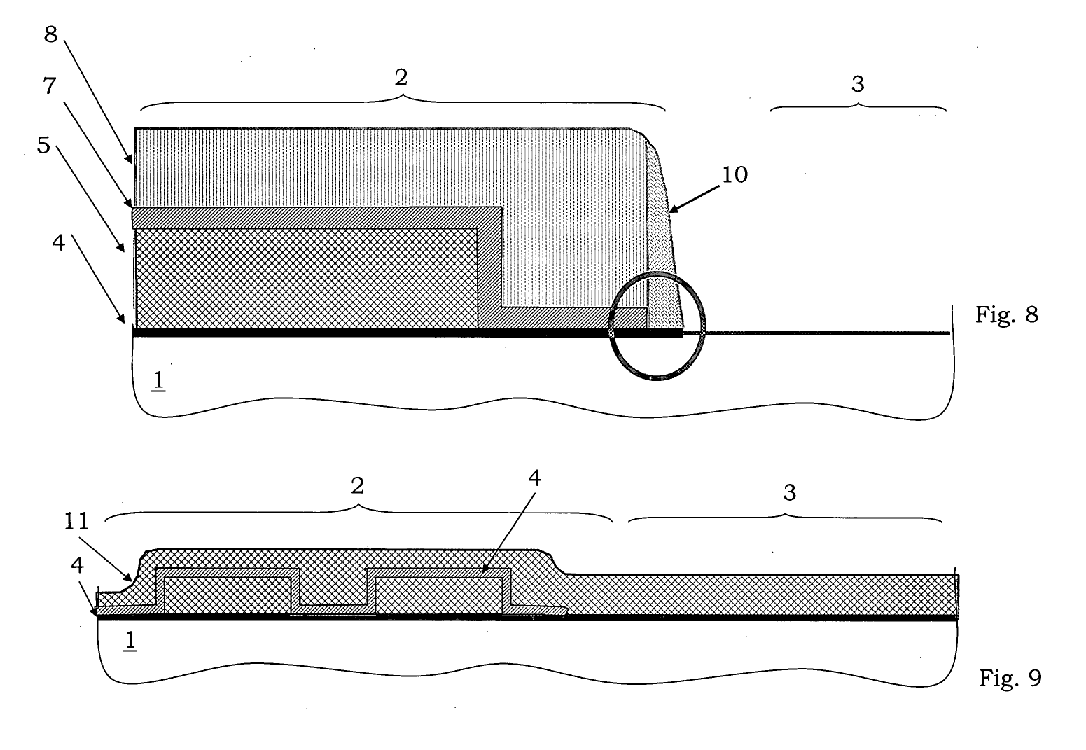

An etching step of the protective layer 9 is then carried out from all the horizontal surfaces. In particular, the etching step of the protective layer 9 is carried out via a dry etching step of the anisotropic type which is very selective with respect to the insulation layer 4 formed on the circuitry 3. In this way, portions 10 of the protective layer 9 are confined on the side walls of the mask 8 and of the interpoly insulation layer 7, as shown in FIG. 8.

Thus, according to the invention, the portions 10 of the protective layer 9 surround the areas which are to be protected by the successive wet etching step of the isotropic type. Advantageously, the height of the portions 10 and their distance from the surface of the structure (ONO or poly) is not binding for the purposes of the method according to the invention, while the length of the of the portions 10 depends on the layout rules, i.e. on the distances to be respected for removing the insulating layer 7.

In particular, by forming the protective layer 9 via a resist layer, the thickness of this resist layer 9 is about 1000 Å. Such a thickness of the resist layer 9 also takes into account the reduction of the same layer which occurs after the UV thermal treatment which is carried out for preparing the resist layer for the successive dry etching.

The process is completed via the wet etching steps of the isotropic type suitable for removing the insulation layers 4 left exposed by the mask 8. According to the invention, the resist mask 8 protects the area of the memory matrix 2, but nothing prevents this mask 8 from covering other portions of the semiconductor substrate 1 where other electronic devices are formed. These devices are for example capacitors, which use the interpoly insulation layer 7 as dielectric layer between the respective armatures.

Further portions 10 of the protective layer 9 will surround also the portion of the resist mask 8 formed in correspondence with the capacitors. Thus, according to the invention, the interpoly insulation layer 7 below the resist mask 8 cannot be removed since it is laterally protected by the portions 10 of the protective layer 9.

At this point, the method according to the invention follows with the conventional steps of the processes for manufacturing non-volatile memory cells, after having completely removed the protective layer 9 and the mask 8. These steps initially provide the formation of a second polysilicon layer 11, as shown in FIG. 9.

The definition of the floating gate regions of the cells of the matrix 2 is then carried out via a conventional photolithographic process using a mask, called self-alignment mask, and the definition of the gates of the transistors of the circuitry 3 via a conventional photolithographic process using an exposure of a mask, called mask of the circuitry 3. The formation of contacts and metallization layers then follows.

In conclusion, the method according to the invention prevents the penetration of the wet isotropic etching solution below the mask 8 made of a DUV resist layer which is a material particularly sensitive to this etching process. The method according to the invention thus, besides safeguarding some critical layers essential for the operation of the device, also perform an anti-angling function of the DUV resist of the mask 8 from the insulation layer 7. In this way, the ‘corrosion’ of the upper part of the interpoly insulation layer in the memory cells and possibly in other devices formed on the semiconductor substrate 1, such as for example the capacitors, is avoided.

1-8. (canceled)

9. A method for manufacturing an electronic memory device on a semiconductor substrate including a non volatile memory matrix and associated circuitry, the method comprising:
forming a first insulation layer on the semiconductor substrate;
forming a conductive layer on the first insulation layer;
forming a second insulation layer on the conductive layer;
forming a resist mask on the second insulation layer at least corresponding to the memory matrix to define exposed areas in the second insulation layer;
isotropically etching the exposed areas of the second insulation layer;
forming a conformal protective layer over the resist mask, insulation and conductive layers;
etching the conformal protective layer to form portions of the protective layer on side walls of the resist mask and of the second insulation layer;
isotropically etching the first insulation layer exposed by the resist mask and by the protective layer portions; and
removing the protective layer portions and the resist mask.

10. The method according to claim 9, wherein etching the conformal protective layer comprises-highly selective etching with respect to the first insulation layer to form the protective layer portions on side walls of the resist mask and the insulation layer.

11. The method according to claim 9, wherein the conformal protective layer comprises a Deep Ultra Violet (DUV) resist layer.

12. The method according to claim 9, wherein the conformal protective layer is etched with a anisotropic type etchant.

13. The method according to claim 9, wherein the conformal protective layer comprises a resist layer different from the resist mask.

14. The method according to claim 13, further comprising hardening the resist layer via a thermal treatment.

15. The method according to claim 13, wherein the resist layer has a thickness of about 1000 Å.

16. The method according to claim 9 wherein the conformal protective layer comprises a Bottom Antireflective Coating (BARC) layer.

17. The method according to claim 9 wherein the resist mask is also formed on the second insulation layer corresponding to the associated circuitry.

18. A method for manufacturing a semiconductor memory device, the method comprising:
forming a first insulation layer on a semiconductor substrate;
forming a conductive layer on the first insulation layer;
forming a second insulation layer on the conductive layer;
forming a resist mask on the second insulation layer to define exposed areas in the second insulation layer;
etching the exposed areas of the second insulation layer;
forming a conformal protective layer over the resist mask, insulation and conductive layers;
etching the conformal protective layer to form protective layer portions on side walls of the resist mask and of the second insulation layer;
etching the first insulation layer exposed by the resist mask and by the protective layer portions.

19. The method according to claim 18 further comprising removing the protective layer portions and the resist mask.

20. The method according to claim 18, wherein etching the conformal protective layer comprises highly selective etching with respect to the first insulation layer to form the protective layer portions on side walls of the resist mask and the insulation layer.

21. The method according to claim 18, wherein the conformal protective layer comprises a Deep Ultra Violet (DUV) resist layer.

22. The method according to claim 18, wherein the conformal protective layer is etched with a anisotropic type etchant.

23. The method according to claim 18, wherein the conformal protective layer comprises a resist layer different from the resist mask.

24. The method according to claim 23, further comprising hardening the resist layer via a thermal treatment.

25. The method according to claim 23, wherein the resist layer has a thickness of about 1000 Å.

26. The method according to claim 18 wherein the conformal protective layer comprises a Bottom Antireflective Coating (BARC) layer.
